(19) United States
(12) Patent Application Publication
(10) Pub. No.: US 2015/0083189 A1
(43) Pub. Date: Mar. 26, 2015

(54) COATINGS FOR AIRCRAFT FUSELAGE SURFACES TO PRODUCE ELECTRICITY FOR MISSION-CRITICAL SYSTEMS ON MILITARY AIRCRAFT

(71) Applicants: John Anthony CONKLIN, Apalachin, NY (US); Scott Ryan HAMMOND, Wheat Ridge, CO (US)

(72) Inventors: John Anthony CONKLIN, Apalachin, NY (US); Scott Ryan HAMMOND, Wheat Ridge, CO (US)

(73) Assignee: NEW ENERGY TECHNOLOGIES, INC., Columbia, MD (US)

(21) Appl. No.: 14/317,939

(22) Filed: Jun. 27, 2014

Related U.S. Application Data
(60) Provisional application No. 61/841,243, filed on Jun. 28, 2013.
(60) Provisional application No. 61/842,355, filed on Jul. 2, 2013.
(60) Provisional application No. 61/841,244, filed on Jun. 28, 2013.
(60) Provisional application No. 61/842,357, filed on Jul. 2, 2013.
(60) Provisional application No. 61/841,247, filed on Jun. 28, 2013.
(60) Provisional application No. 61/842,365, filed on Jul. 2, 2013.
(60) Provisional application No. 61/841,248, filed on Jun. 28, 2013.
(60) Provisional application No. 61/842,372, filed on Jul. 2, 2013.
(60) Provisional application No. 61/842,796, filed on Jul. 3, 2013.
(60) Provisional application No. 61/841,251, filed on Jun. 28, 2013.
(60) Provisional application No. 61/842,375, filed on Jul. 2, 2013.
(60) Provisional application No. 61/842,803, filed on Jul. 3, 2013.

(51) Int. Cl. H02S 10/40; B32B 37/12; H01L 51/44; B32B 37/00; H02S 30/20; H01L 51/00; B32B 37/24; B32B 38/10

(52) U.S. Cl. CPC H02S 10/40; B32B 37/24; B32B 37/12; B32B 38/10; B32B 37/025; H02S 30/20; H01L 51/0097; H01L 51/448; B32B 2037/243; B32B 2605/18
USPC 136/245; 156/60; 156/247; 136/263

(57) ABSTRACT

A variety of methods for fabricating organic photovoltaic-based electricity-generating military aircraft fuselage surfaces are described. In particular, a method for fabricating curved electricity-generating military aircraft fuselage surfaces utilizing lamination of highly flexible organic photovoltaic films is described. High-throughput and low-cost fabrication options also allow for economical production.

### CROSS-REFERENCE TO RELATED APPLICATIONS

This application claims priority under 35 U.S.C. 119(e) of U.S. Provisional Application No. 61/841,243, filed on Jun. 28, 2013 (Attorney Docket No. 7006/0141PR01), U.S. Provisional Application No. 61/842,355, filed on Jul. 2, 2013 (Attorney Docket No. 7006/0141PR02), U.S. Provisional Application No. 61/841,244, filed on Jun. 28, 2013 (Attorney Docket No. 7006/0142PR01), U.S. Provisional Application No. 61/842,357, filed on Jul. 2, 2013 (Attorney Docket No. 7006/0142PR02), U.S. Provisional Application No. 61/841,247, filed on Jun. 28, 2013 (Attorney Docket No. 7006/0143PR01), U.S. Provisional Application No. 61/842,365, filed on Jul. 2, 2013 (Attorney Docket No. 7006/0143PR02), U.S. Provisional Application No. 61/841,248, filed on Jun. 28, 2013 (Attorney Docket No. 7006/0144PR01), U.S. Provisional Application No. 61/842,372, filed on Jul. 2, 2013 (Attorney Docket No. 7006/0144PR02), U.S. Provisional Application No. 61/842,796, filed on Jul. 3, 2013 (Attorney Docket No. 7006/0145PR01), U.S. Provisional Application No. 61/841,251, filed on Jun. 28, 2013 (Attorney Docket No. 7006/0146PR01), U.S. Provisional Application No. 61/842,375, filed on Jul. 2, 2013 (Attorney Docket No. 7006/0146PR02) and U.S. Provisional Application No. 61/842,803, filed on Jul. 3, 2013 (Attorney Docket No. 7006/0147PR01); the entire contents of all the above identified patent applications are hereby incorporated by reference in their entirety. This application is related to Applicants' co-pending U.S. applications, which are filed concurrently herewith on Jun. 27, 2014, 7006/0141PUS01, 7006/0143PUS01, 7006/0144PUS01, 7006/0145PUS01, 7006/0146PUS01 and 7006/0147PUS01; each of which is incorporated herein by reference in its entirety.

### FIELD OF THE INVENTION

The present invention is directed to the use of organic photovoltaic devices—cell or modules—as coatings for military aircraft fuselage, wing, tail, and strut surfaces, to provide electricity for mission-critical systems on-board the aircraft.

### BACKGROUND OF THE INVENTION

Modern military aircraft are highly technologically advanced vehicles that must perform a variety of duties under very demanding conditions. Energy efficiency and energy consumption are of minimal concern in such vehicles, but the military is constantly looking to make every surface into an active one, through the use of advanced materials. Despite this, the majority of military aircraft surfaces (fuselage, wing, tail, strut, etc.) remain largely passive, non-functional surfaces. If value could be added to these surfaces by making them contribute to the overall mission-capability of the aircraft by producing electrical energy, it would be a significant improvement, regardless of cost.

### SUMMARY OF THE INVENTION

The present invention recognizes that one way to add functionality to aircraft surfaces is by covering them in photovoltaics (PV), which can provide electricity to help power mission-critical systems on-board the aircraft. Traditional inorganic PV makes little sense for aircraft applications for a number of reasons, however, including excessive weight and potentially bulky structures that could increase wind resistance, both of which would reduce fuel efficiency. Organic PV (OPV) has a number of features that makes it potentially attractive for application in military aircraft, including low specific weight (W/g), flexibility, and thickness of the thin films. An important feature is the very low specific weight of OPV, as compared to other PV technologies, which could minimize any impact on fuel efficiency. Additionally, OPV is inherently flexible, which potentially allows unique application methods for non-planar surfaces, such as curved fuselage surfaces. Furthermore, the tunable nature of the absorption in OPV materials allows customized power production and surface appearances, which can be important for specialized military aircraft.

The present invention recognizes that conventional military aircraft surfaces, such as fuselage, wing, tail, and strut surfaces (hereafter referred to simply as fuselage surfaces), are generally passive surfaces that do not contribute actively to the mission-capability of the aircraft.

These problems and others are addressed by the present invention, a first exemplary embodiment of which comprises an OPV device, comprising one or more cells connected in series and/or parallel, applied as a film to conventional military aircraft surfaces. In this embodiment, the OPV coating is applied as a completed device onto the aircraft surface using a thin, flexible substrate with pressure-sensitive adhesives, which is described in detail in Applicants' related applications. In such a fashion, the OPV device can be fabricated in a high-throughput manner via roll-to-roll manufacturing onto a flexible planar substrate (with backing material, if necessary) that is then applied to both planar and curved aircraft surfaces. The OPV device can then be wired into the electrical systems via small connection terminals in, or below, the aircraft surface, and any necessary power electronics, such as inverters, batteries, and the like can be located inside the aircraft. The top surface of the OPV device-coated aircraft is then via a protective hard clear-coat (e.g. a clear epoxy coating), to protect the OPV device from physical damage and environmental stress, and from moisture and oxygen ingress, ensuring a superior lifetime. In such a way, the surfaces of the aircraft can be turned into electricity-generating surfaces to help power mission-critical systems, while adding minimal weight, and resulting in a smooth, hard, low-drag surface, to minimize any loss of fuel efficiency. Furthermore, by selecting appropriate OPV material absorption properties, the surface visual effect can be matched to the aircraft design profile, while still generating power.

Another exemplary embodiment of the invention comprises an OPV device—comprising one or more cells connected in series and/or parallel—fabricated directly on the conventional aircraft surfaces, before assembly of the aircraft. In this embodiment, the surfaces are coated via one or more of a number of techniques, such techniques as: spray, curtain, slot-die, gravure, etc. depending on the curvature of the aircraft surface being coated. Spray and curtain coating can be utilized for curved surfaces, while slot-die and gravure coating can be used for planar surfaces. First, an insulating layer is deposited to allow isolation of the individual cells from each other and from the metal aircraft surfaces, to prevent electrification of the entire aircraft body. Then, the rest of the OPV device is deposited as usual via the appropriate coating and patterning techniques, as known to those skilled in the art of OPV, to produce a completed device directly on the aircraft surface. Again, wiring is accomplished via small terminals on, or below, the aircraft surface, and a hard top clear-coat (e.g., epoxy), is applied to provide a hard, low-drag surface that protects the OPV device. Such completed OPV-coated aircraft surface panels can then be assembled directly on the aircraft body, with wiring and any necessary power electronics, such as inverters and batteries, placed inside the aircraft body to produce a military aircraft with electricity-producing surfaces to help power mission-critical systems on-board.

Other features and advantages of the present invention will become apparent to those skilled in the art upon review of the following detailed description and drawings.

### BRIEF DESCRIPTION OF THE DRAWINGS

These and other aspects and features of embodiments of the present invention will be better understood after a reading of the following detailed description, together with the attached drawings, wherein:

FIG. 1 is a cross-sectional view of a pressure-sensitive adhesive-coated organic photovoltaic device, itself coated on a thin flexible substrate with a transfer release layer and rigid backing layer, which can be used to prepare planar and curved organic photovoltaic device-covered military aircraft fuselage surfaces, according to an exemplary embodiment of this invention, as well as Applicant's related application.

FIG. 2 is a cross-sectional view of an organic photovoltaic device coated onto a planar military aircraft fuselage surface using the pressure-sensitive adhesive method according to an exemplary embodiment of the invention.

FIG. 3 is a cross-sectional view of an organic photovoltaic device coated onto a curved military aircraft fuselage surface using the pressure-sensitive adhesive method according to an exemplary embodiment of the invention.

FIG. 4 is a cross-sectional view of an organic photovoltaic device coated directly onto a planar military aircraft fuselage surface using conventional coating methods according to an exemplary embodiment of the invention.

FIG. 5 is a cross-sectional view of an organic photovoltaic device coated directly onto a curved military aircraft fuselage surface using conventional coating methods according to an exemplary embodiment of the invention.

### DETAILED DESCRIPTION OF THE EXEMPLARY EMBODIMENTS OF THE INVENTION

The present invention now is described more fully hereinafter with reference to the accompanying drawings, in which embodiments of the invention are shown. This invention may, however, be embodied in many different forms and should not be construed as limited to the embodiments set forth herein; rather, these embodiments are provided so that this disclosure will be thorough and complete, and will fully convey the scope of the invention to those skilled in the art.

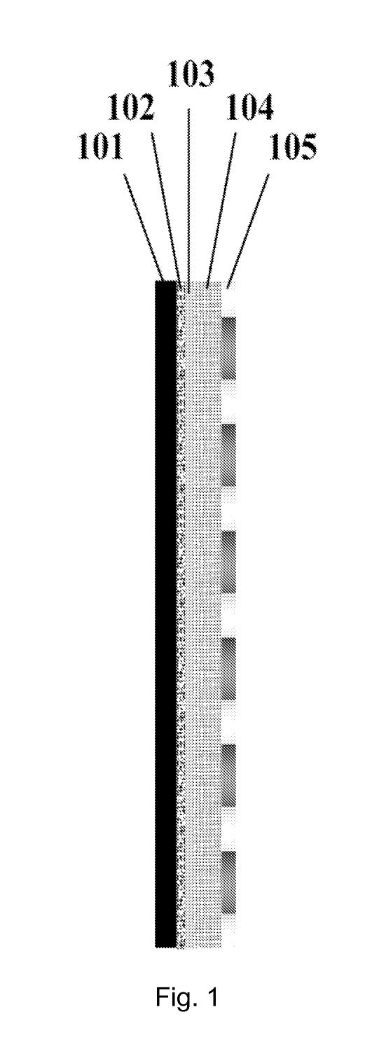

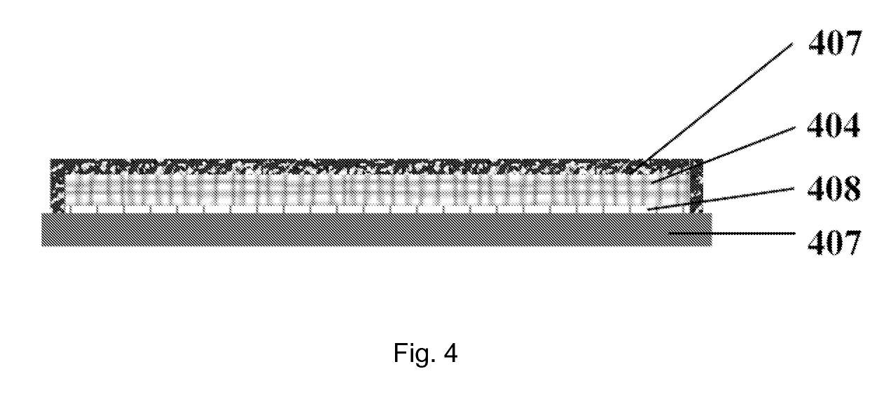

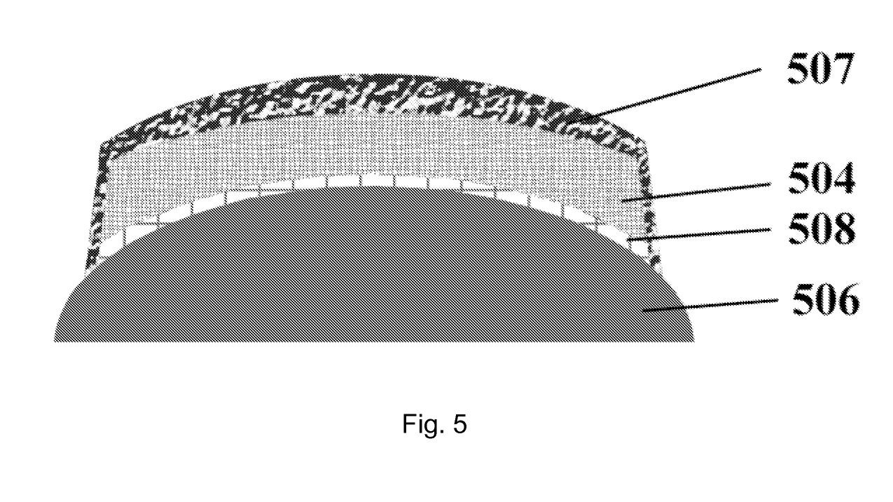

Referring now to the drawings, FIGS. 1-5 illustrate exemplary embodiments of electricity-generating coatings for military aircraft fuselage surfaces (FIGS. 4-5) and their manufacture (FIG. 1).

Referring to FIG. 1, which provides a cross-sectional view of an intermediate film stack produced for the eventual fabrication of electricity-generating coatings for military aircraft fuselage surfaces, the film is prepared upon a temporary base layer 101, in order to provide sufficient rigidity to allow conventional manufacturing techniques, including high-speed roll-to-roll coating. The base layer can include of thick polymer foils, metal foils, glass substrates, or any convenient substrate material, depending on the chosen manufacturing methods. On top of the base layer is a transfer release layer 102 that allows easy removal of the base layer and transfer layer from the thin flexible substrate 103, which are all laminated together as known to those skilled in the art. The thin flexible substrate is any appropriate substrate material that is highly flexible and transparent, such as very thin polymer foils, including but not limited to polyethyleneterephthalate (PET). On top of this is coated an OPV device, comprising one or more cells connected in series and/or parallel, which is inherently flexible and thus contains no highly crystalline materials. The multi-layered OPV device is coated and processed according to standard methods known to those skilled in the art, such as slot-die coating and laser scribing, which are compatible with high-throughput manufacturing techniques, including high-speed roll-to-roll or sheet-to-sheet production methods. Finally, the OPV device is coated on top with a semitransparent pressure-sensitive adhesive according to methods know to those skilled in the art. The resulting film comprising layers 101-105 can be used to transfer the OPV device comprising layers 103-105 onto military aircraft fuselage surfaces to convert them into electricity-generating fuselage surfaces.

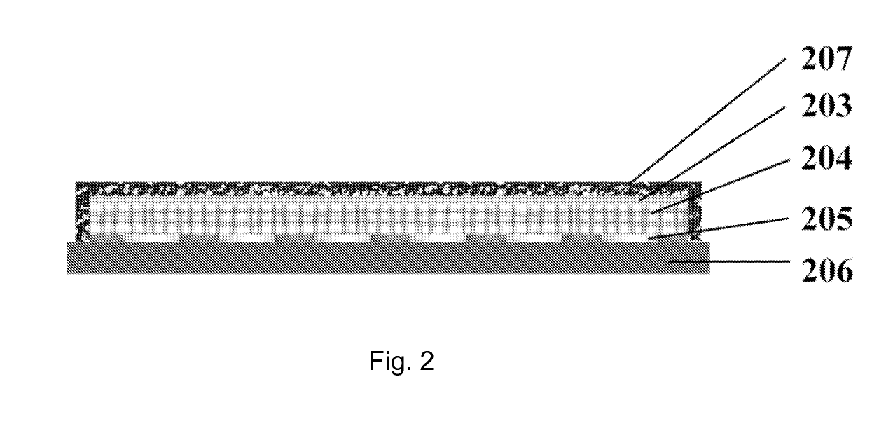

Referring to FIG. 2, which provides a cross-sectional view of a planar electricity-generating military aircraft fuselage surface produced via the pressure-sensitive adhesive method, the base layer 206 includes a conventional military aircraft fuselage panel. Laminated onto the fuselage panel using stretching and press-forming, with or without vacuum assistance in removing entrained air, is the electricity-generating OPV device 204, which is adhered to the panel using the pressure-sensitive adhesive layer 205, and is supported by the thin flexible substrate layer 203. Finally, the whole OPV device is protected via a clear hard-coat 207 (e.g. a clear epoxy), which can be applied via a variety of techniques known to those skilled in the art, such as spray coating. While, in this exemplary embodiment, the method is necessarily a discrete object process for the fabrication of each individual fuselage panel, the intermediate transfer film (see FIG. 1) used to transfer the completed OPV device onto the panel can be produced in a continuous, high-throughput methodology. Not shown are any wires or other electrical contacts, or any power circuitry (e.g. inverters), which would be contained largely within the aircraft body.

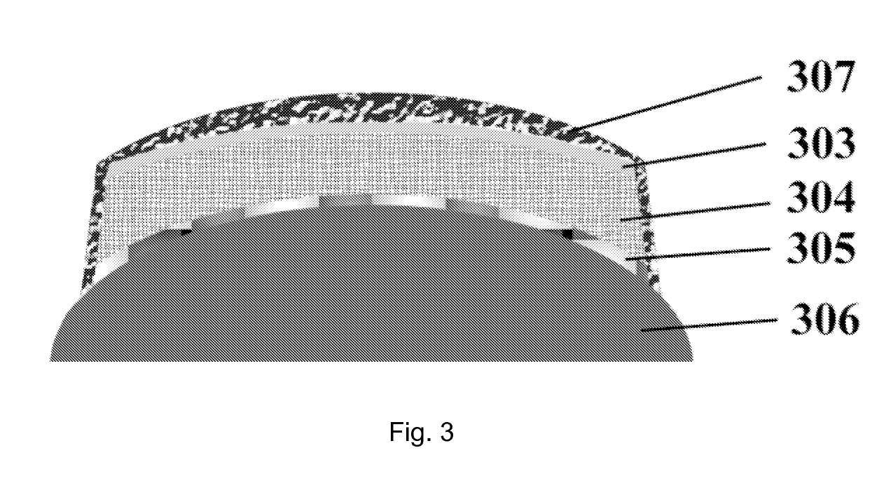

Referring to FIG. 3, which provides a cross-sectional view of a curved electricity-generating military aircraft fuselage surface produced via the pressure-sensitive adhesive method, the base layer 306 includes a conventional curved military aircraft fuselage surface. Laminated onto the fuselage panel using stretching and press-forming, with or without vacuum assistance in removing entrained air, is the electricity-generating OPV device 304, which is adhered to the panel using the pressure-sensitive adhesive layer 305, and is supported by the thin flexible substrate layer 303. Finally, the whole OPV device is protected via a clear hard-coat 307 (e.g. a clear epoxy), which can be applied via a variety of techniques known to those skilled in the art, such as spray coating. The unique and inherent flexibility of OPV devices allows lamination onto curved surfaces without significant disruption of device performance, and enables production of three-dimensional OPV devices that would be difficult to produce via conventional coating techniques due to realities of capillarity flow on curved surfaces. This method enables OPV devices to be laminated onto surfaces of arbitrary and changing curvature, which would be impossible via conventional solution coating techniques. While, in this exemplary embodiment, the method is necessarily a discrete object process for the fabrication of each individual fuselage panel, the intermediate transfer film (see FIG. 1) used to transfer the completed OPV device onto the panel can be produced in a continuous, high-throughput methodology. Not shown are any wires or other electrical contacts, or any power circuitry (e.g. inverters), which would be contained largely within the aircraft body.

Referring to FIG. 4, which provides a cross-sectional view of a planar electricity-generating military aircraft fuselage surface produced via the conventional coating method, the base layer 406 includes a conventional military aircraft fuselage surface. First, the fuselage surface is coated with an insulating layer 408 using methods known to those skilled in the art, to allow isolation of the individual cells from each other and from the aircraft body, preventing electrification of the entire aircraft body. The OPV device 404 is then coated onto the insulating layer using conventional coating techniques such as known to those skilled in the art. Finally, the whole OPV device is protected via a clear hard-coat 407 (e.g. a clear epoxy), which can be applied via a variety of techniques known to those skilled in the art, such as spray coating. While this method has the advantage of having less extraneous layers and materials involved as compared to the laminated processes (see FIG. 2), in this exemplary embodiment, it is necessarily a sheet-to-sheet coating process performed on a panel-by-panel basis for every individual layer in the OPV device, which can limit throughput and increase defects, compared to producing the OPV device in a continuous process (see FIG. 1). Not shown are any wires or other electrical contacts, or any power circuitry (e.g. inverters), which would be contained largely within the aircraft body.

Referring to FIG. 5, which provides a cross-sectional view of a curved electricity-generating military aircraft fuselage surface produced via the conventional coating method, the base layer 506 includes a conventional military aircraft fuselage surface. First, the fuselage surface is coated with an insulating layer 508 using methods known to those skilled in the art, to allow isolation of the individual cells from each other and from the aircraft body, preventing electrification of the entire aircraft body. The OPV device 504 is then coated onto the insulating layer using conventional coating techniques such as spray or curtain coating. Finally, the whole OPV device is protected via a clear hard-coat 507 (e.g. a clear epoxy), which can be applied via a variety of techniques known to those skilled in the art, such as spray coating. While the realities of capillarity flow make precision coating of the very thin layers in OPV devices very difficult, it is possible to overcome these limitations, as least for surfaces with relatively uniform curvature. Doing so repeated for the several layers in an OPV device remains a significant challenge, however, and it is currently impossible for surfaces with varying or very high curvature. As such, the pressure-sensitive adhesive lamination method presents an attractive alternative for the production of curved fuselage surfaces (see FIG. 3).

The present invention has been described herein in terms of several preferred embodiments. However, modifications and additions to these embodiments will become apparent to those of ordinary skill in the art upon a reading of the foregoing description. It is intended that all such modifications and additions comprise a part of the present invention to the extent that they fall within the scope of the several claims appended hereto.

What is claimed is:

1. An electricity-generating coating for military aircraft fuselage surfaces comprising:
a conformal organic photovoltaic device, including one or more cells connected in series and/or parallel,
adhered to aircraft fuselage panel surfaces,
along with the wires and power electronics to allow such coatings to provide electricity for mission-critical systems on-board the aircraft.

2. The electricity-generating coating of claim 1, wherein the organic photovoltaic device is adhered to the military aircraft fuselage surfaces using a pressure-sensitive adhesive.

3. The electricity-generating coating of claim 2, wherein the organic photovoltaic device is covered by a very thin, highly flexible transparent substrate, such as polyethylene terephthalate (PET).

4. The electricity-generating coating of claim 3, wherein the organic photovoltaic device is protected by a hard, clear top-coat material, such as an epoxy.

5. The electricity-generating coating of claim 4, wherein the military aircraft fuselage surface is completely planar (flat).

6. The electricity-generating coating of claim 4, wherein the military aircraft fuselage surface is curved.

7. The electricity-generating coating of claim 1, wherein:
the military aircraft fuselage panels are coated in an insulating material,
and the organic photovoltaic device is coated on the insulating material.

8. The electricity-generating coating of claim 7, wherein the organic photovoltaic device is protected by a hard, clear top-coat material, such as an epoxy.

9. The electricity-generating coating of claim 8, wherein the military aircraft fuselage surface is completely planar (flat).

10. The electricity-generating coating of claim 4, wherein the military aircraft fuselage surface is curved.

11. A transfer film comprising:
a support substrate,
a transfer release layer laminated between the rigid support substrate and a very thin, highly flexible transparent substrate, such as PET,
an organic photovoltaic device, comprising one or more cells connected in series and/or parallel,
and a pressure-sensitive adhesive

12. The transfer film of claim 11, wherein the support substrate is a rigid material such as glass or thick metal.

13. The transfer film of claim 11, wherein the support substrate is a flexible material, such as a polymer or metal foil compatible with roll-to-roll manufacturing techniques.

14. A method for the manufacture of the flexible transfer film of claim 13, wherein:
the flexible foil is coated with the transfer release material,
laminated with the very thin, highly flexible transparent substrate, such as PET,
coated with the multilayer organic photovoltaic device,
and coated with a pressure-sensitive adhesive,
all in a roll-to-roll manner,
and utilizing solution-processing,
to allow low-cost, high-throughput manufacturing.

15. A method for the fabrication of the electricity-generating coating of claim 3, wherein:
the transfer film of claim 11 is applied to the military aircraft fuselage surface in such a way as to adhere the pressure-sensitive adhesive to the fuselage surface,
lamination, stretching, press-forming, and/or vacuum removal of air entrainment are utilized to ensure conformal adhesion,
the backing substrate and transfer release layer are removed.

16. A method for the fabrication of the electricity-generating coating of claim 6, wherein:
the transfer film of claim 13 is applied to a curved military aircraft fuselage surface in such a way as to adhere the pressure-sensitive adhesive to the fuselage surface,
lamination, stretching, press-forming, and/or vacuum removal of air entrainment are utilized to ensure conformal adhesion,
the backing substrate and transfer release layer are removed.
